(19) United States
(12) Patent Application Publication
(10) Pub. No.: US 2023/0282531 A1
(43) Pub. Date: Sep. 7, 2023

(54) FAN-OUT WATER-LEVEL PACKAGING STRUCTURE AND MANUFACTURING METHOD THEREOF

(71) Applicant: JCET ADVANCED PACKAGING CO., LTD., Wuxi City (CN)

(72) Inventors: XIA XU, Wuxi City (CN); HONG XU, Wuxi City (CN); HAIJIE CHEN, Wuxi City (CN)

(21) Appl. No.: 18/116,296

(22) Filed: Mar. 1, 2023

(30) Foreign Application Priority Data
Mar. 2, 2022 (CN) 202210198835.7

(51) Int. Cl. H01L 23/16; H01L 23/00; H01L 23/498; H01L 23/31; H01L 23/29; H01L 21/56

(52) U.S. Cl. CPC H01L 23/16; H01L 21/561; H01L 21/568; H01L 23/293; H01L 23/3128; H01L 23/49816; H01L 23/49838; H01L 24/08; H01L 24/16; H01L 24/96; H01L 24/97; H01L 2224/08235; H01L 2224/16235; H01L 2224/96; H01L 2224/97; H01L 2924/1011; H01L 2924/15174; H01L 2924/15311

(57) ABSTRACT

The present invention provides a wafer-level fan-out structure and a manufacturing method thereof. The wafer-level fan-out structure includes a plurality of chips, a sheet-like structure and a plastic packaging layer. The plastic packaging layer covers the plurality of chips and the sheet-like structure. The sheet-like structure includes a first region and a second region. The first region includes a plurality of spaced apertures, and each aperture is adjacent to the second region. The plurality of chips and the plurality of apertures are in one-to-one correspondence, and each chip is located in the corresponding aperture. A Young’s modulus of the plastic packaging layer is smaller than that of the sheet-like structure, and a ratio of an area of the first region to an area of the second region is (0.5-2):1. The wafer-level fan-out structure can remarkably reduce package warpage and achieves better package strength.

### TECHNICAL FIELD

The present invention belongs to the field of semiconductor packaging technologies, and particularly relates to a wafer-level fan-out structure and a manufacturing method thereof.

### BACKGROUND

The fan-out wafer-level package (FOWLP) technology is an improvement of the wafer-level package (WLP) technology and can provide more external connections for a single chip. In the FOWLP technology, chips are embedded into a plastic packaging material, then a high-density redistribution layer (RDL) is built on the surface of a wafer, and solder balls are applied to form a reconstituted wafer.

In the process of manufacturing the reconstituted wafer, the chips are coated and packaged with a cladding material, and the fan-out ratio (ratio of package size/chip size) may significantly affect the warpage of the reconstituted wafer or a large panel. An excessively high or low fan-out ratio may cause excessive warpage of the reconstituted wafer, making production impossible.

Currently, the use of a cladding material with a relatively low Young’s modulus can reduce the warpage of chips in a cladding and packaging process and the warpage of a finished product, and reduce the influence of the fan-out ratio on the warpage. However, the low Young’s modulus of the cladding material may lead to insufficient strength of a package.

In view of this, it is necessary to provide a novel wafer-level fan-out structure to solve the aforementioned problem of insufficient strength of the package due to the low Young’s modulus of the cladding material.

### SUMMARY

An object of the present invention is to provide a wafer-level fan-out structure and a manufacturing method thereof, in which the warpage of a reconstituted wafer in the FOWLP technology is avoided while the strength of the wafer-level fan-out structure is enhanced by embedding a sheet-like structure in a plastic packaging layer.

To solve the above problem, the technical solution of the present invention provides a wafer-level fan-out structure. The wafer-level fan-out structure includes a plurality of chips, a sheet-like structure and a plastic packaging layer. The plastic packaging layer covers the plurality of chips and the sheet-like structure. The sheet-like structure includes a first region and a second region. The first region includes a plurality of spaced apertures, and each aperture is adjacent to the second region. The plurality of chips and the plurality of apertures are in one-to-one correspondence, and each chip is located in the corresponding aperture. The Young’s modulus of the plastic packaging layer is lower than that of the sheet-like structure, and the ratio of the area of the first region to the area of the second region is (0.5-2): 1.

As an optional technical solution, each chip includes an active surface and a connection terminal, and the connection terminal is located on the active surface. The wafer-level fan-out structure further includes: a redistribution layer disposed on the active surface side and electrically connected to the connection terminal; and an interconnection structure which is disposed on a side surface of the redistribution layer away from the connection terminal and is electrically connected to the redistribution layer.

As an optional technical solution, the plastic packaging layer covers the chip and the sheet-like structure on the active surface side, the connection terminal is exposed from a surface of the plastic packaging layer away from the active surface, and the redistribution layer is disposed on a surface of the plastic packaging layer.

As an optional technical solution, the chip includes a back surface facing away from the active surface. The plastic packaging layer covers the chip and the sheet-like structure on a back surface side, wherein the active surface is not covered with the plastic packaging layer, and the redistribution layer is disposed on the active surface and the surface of the sheet-like structure not covered with the plastic packaging layer.

As an optional technical solution, the sheet-like structure further includes a metal post; the metal post is embedded into the second region and includes a connection end surface; the connection end surface and the connection terminal are located on the same side; and the connection end surface and the redistribution layer are electrically connected to each other.

As an optional technical solution, the ratio of the thickness of the sheet-like structure, the film thickness of the plastic packaging layer and the thickness of the chip is (0.5-2):(1-2): 1.

As an optional technical solution, the sheet-like structure is made of pure metal, alloy, organic resin or a combination thereof.

As an optional technical solution, the alloy is hard alloy or stainless steel.

As an optional technical solution, the organic resin is epoxy resin, phenolic resin, amino resin or unsaturated polyester resin.

As an optional technical solution, the sheet-like structure further includes a plurality of cutting lines, the plurality of cutting lines are located in the second region and surround the plurality of apertures, and a plurality of single packages are obtained by cutting the wafer-level fan-out structure along the plurality of cutting lines.

As an optional technical solution, in each single package, the ratio of the area of the chip to the area of the plastic packaging layer surrounding the chip is 1:(1-15); and the ratio of the area of the chip to the area of the sheet-like structure surrounding the chip is 1:(1-15), wherein the area of the sheet-like structure surrounding the chip is less than or equal to the area of the plastic packaging layer.

The present invention further provides a manufacturing method of a wafer-level fan-out structure, including:
providing a carrier plate having a temporary bonding layer disposed on one surface thereof;
providing a sheet-like structure, the sheet-like structure including a first region and a second region, the first region including a plurality of spaced apertures, and each aperture being adjacent to the second region; securing the sheet-like structure to the temporary bonding layer;
providing a plurality of chips, and mounting the plurality of chips into the plurality of corresponding apertures, connection terminals being disposed on active surfaces of the chips; and
coating with a plastic packaging material, the plastic packaging material covering the sheet-like structure and the plurality of chips,
wherein a Young’s modulus of the plastic packaging layer is lower than that of the sheet-like structure, and the ratio of the area of the first region to the area of the second region is (0.5-2):1.

As an optional technical solution, the manufacturing method further includes: forming a redistribution layer on the active surface, the redistribution layer and the connection terminal being electrically connected to each other; and manufacturing an interconnection structure on a portion of the redistribution layer away from the active surface.

As an optional technical solution, the manufacturing method further includes: making the connection terminal protrude away from the carrier plate, a back surface of the chip being temporarily bonded to the temporary bonding layer; coating an active surface side with a plastic packaging material, the plastic packaging material covering the sheet-like structure and the chip; stripping the temporary bonding layer and the carrier plate; thinning the plastic packaging layer until the connection terminal is exposed from a surface of the plastic packaging layer away from the active surface; and forming the redistribution layer on a surface of the thinned plastic packaging layer.

As an optional technical solution, the manufacturing method further includes: temporarily bonding the connection terminal to the temporary bonding layer, a back surface of the chip being away from the carrier plate; coating a back surface side with a plastic packaging material, the plastic packaging material covering the sheet-like structure and the chip to constitute the plastic packaging layer; stripping the temporary bonding layer and the carrier plate; and forming the redistribution layer on a surface of the sheet-like structure not covered with the plastic packaging layer and on the active surface.

Compared with the prior art, the present invention provides the wafer-level fan-out structure and the manufacturing method thereof, in which the Young’s modulus of the plastic packaging layer is controlled to be low so as to be able to reduce warpage caused by the plastic packaging layer during reconstitution of the wafer, and the sheet-like structure with a high Young’s modulus is embedded into the plastic packaging layer, so that the package strength can be improved on the one hand, and on the other hand, by use of rigidity of the sheet-like structure, the warpage caused by the plastic packaging layer during reconstitution of the wafer can also be reduced, thereby further reducing the warpage of each single package in the fan-out structure. Selecting the area ratio of the apertures in the sheet-like structure to the sheet-like structure on the one hand effectively reduces the warpage of the wafer-level fan-out structure, and on the other hand, provides enough support to improve the package strength of the wafer-level fan-out structure.

The present invention is described in detail below with reference to the accompanying drawings and specific embodiments, which are not intended to limit the present invention.

### BRIEF DESCRIPTION OF THE DRAWINGS

For clearer descriptions of the technical solutions in the embodiments of the present invention or in the prior art, the following briefly introduces the accompanying drawings required for describing the specific embodiments or the prior art. Apparently, the accompanying drawings in the following description show some embodiments of the present invention, and a person of ordinary skill in the art may still derive other drawings from these accompanying drawings without creative efforts.

FIG. 1 is a schematic sectional view of a wafer-level fan-out structure according to an embodiment of the present invention;

FIG. 2 is a top view of a sheet-like structure according to an embodiment of the present invention;

FIG. 3 is a top view of a sheet-like structure according to another embodiment of the present invention;

FIG. 4 is a schematic sectional view of a manufacturing process of the wafer-level fan-out structure shown in FIG. 1;

FIG. 5 is a schematic sectional view of a manufacturing process of a wafer-level fan-out structure according to another embodiment of the present invention;

FIG. 6 is a schematic sectional view of a manufacturing process of a wafer-level fan-out structure according to yet another embodiment of the present invention;

FIG. 7 is a schematic sectional view of a manufacturing process of a wafer-level fan-out structure according to still another embodiment of the present invention; and

FIG. 8 is a flowchart of a manufacturing method of a wafer-level fan-out structure according to an embodiment of the present invention.

### DETAILED DESCRIPTION

In order to make the objectives, technical solutions and advantages of the present invention clearer, the present invention will be further described in detail below with reference to the embodiments and the accompanying drawings. It should be understood that the specific embodiments described herein are only used to explain the present invention, but not to limit the present invention.

In the description of the present invention, it should be noted that orientation or positional relationships indicated by the terms such as “center”, “upper”, “lower”, “left”, “right”, “vertical”, “horizontal”, “inner”, and “outer” are orientation or positional relationships shown on the basis of the drawings, only for the purposes of facilitating description of the present invention and simplifying the description, but do not indicate or imply that specified apparatuses or elements must have specific directions, or be constructed or operated in the specific directions, and should not be understood as limitations to the present invention.

One of objects of the present invention is to provide a wafer-level fan-out structure in which a sheet-like structure and a chip are embedded into a plastic packaging layer, and the chip is limited by an aperture of the sheet-like structure. The sheet-like structure with a higher Young’s modulus may be configured to enhance the package strength of the wafer-level fan-out structure while a plastic packaging material with a lower Young’s modulus is configured to reduce warpage of the fan-out structure. In addition, a manufacturing process of the wafer-level fan-out structure belongs to the FOWLP technology, in which the presence of the sheet-like structure helps to reduce warpage of a reconstituted wafer and warpage of the wafer-level fan-out structure in the process of manufacturing the reconstituted wafer by plastic-packaging a plurality of chips and the wafer-level sheet-like structure on a carrier plate.

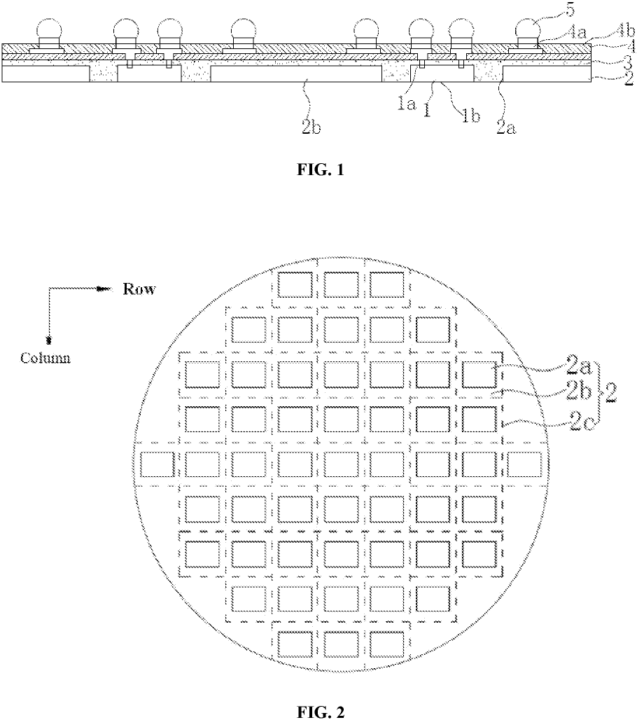

As shown in FIG. 1, an embodiment of the present invention provides a wafer-level fan-out structure, including a plurality of chips 1, a sheet-like structure 2 and a plastic packaging layer 3. The plastic packaging layer 3 covers the plurality of chips 1 and the sheet-like structure 2. The sheet-like structure 2 includes a first region and a second region 2b. The first region includes a plurality of spaced apertures 2a, and each aperture 2a is adjacent to the second region 2b. The plurality of chips 1 and the plurality of apertures 2a are in one-to-one correspondence, and each chip 1 is located in the corresponding aperture 2a. The Young’s modulus of the plastic packaging layer 3 is lower than that of the sheet-like structure 2, and the ratio of the area of the first region to the area of the second region is (0.5-2): 1.

In the wafer-level fan-out structure according to this embodiment, the Young’s modulus of the plastic packaging layer is controlled to be low so as to be able to reduce warpage caused by the plastic packaging layer during reconstitution of a wafer. The sheet-like structure with a high Young’s modulus is embedded into the plastic packaging layer, so that the package strength can be improved on the one hand, and on the other hand, by use of rigidity of the sheet-like structure, the warpage caused by the plastic packaging layer during reconstitution of the wafer can also be reduced, thereby further reducing the warpage of each single package in the fan-out structure. Furthermore, selecting the area ratio of the apertures in the sheet-like structure to the sheet-like structure on the one hand effectively reduces the warpage of the wafer-level fan-out structure, and on the other hand, provides enough support to improve the package strength of the wafer-level fan-out structure.

Continuing to refer to FIG. 1, a connection terminal 1 a is disposed on an active surface of the chip 1, a redistribution layer 4 is disposed on an active surface side, and the redistribution layer 4 and the connection terminal 1a are electrically connected to each other. Specifically, the redistribution layer 4 includes conductive layers 4a and dielectric layers 4b that are alternately stacked. The connection terminal 1a is electrically connected to the conductive layer 4a in the redistribution layer 4.

An interconnection structure 5 is disposed on a side of the redistribution layer 4 away from the active surface and is electrically connected to the conductive layer 4a. The interconnection structure 5 may be a metal bump, a metal post, a solder ball, or a metal post with a tin cap.

As shown in FIGS. 1 and 2, the outer edge of the sheet-like structure 2 is circular when viewed from the top, and the plurality of apertures 2a are arranged in a matrix in row and column directions. Each aperture 2a is, for example, a through hole running through two opposite surfaces of the sheet-like structure 2.

The apertures 2a shown in FIG. 2 take the shape of a rectangle, but are not limited thereto. In other embodiments of the present invention, the apertures may also take any regular or irregular shape such as a quadrangle (a prism, a parallelogram, a trapezoid, etc.), a pentagon, a hexagon, a circle and an ellipse.

In this embodiment, the plurality of apertures 2a constitute the first region, and the sum of the areas of the plurality of apertures 2a equals the area of the first region, while the area of the second region 2b refers to the area of regions other than the apertures 2a in the sheet-like structure 2.

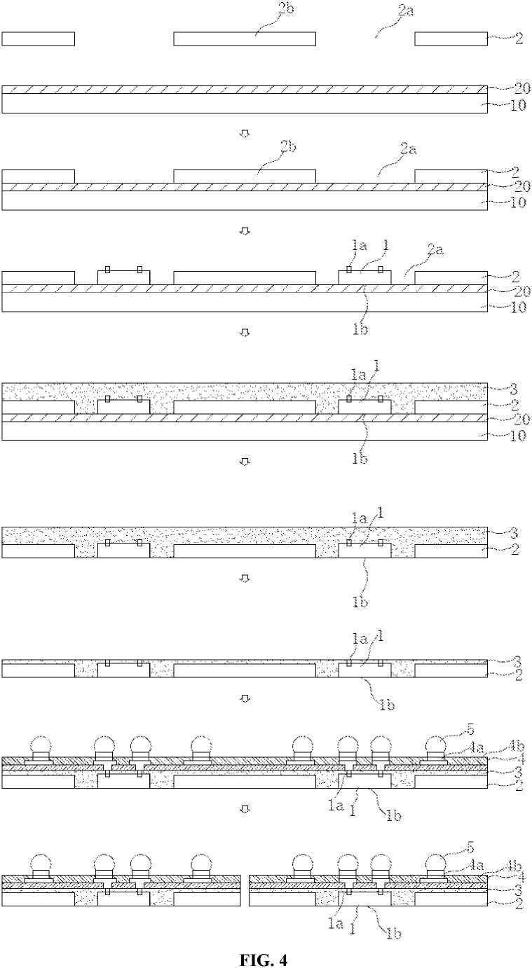

In addition, the sheet-like structure 2 further includes a plurality of cutting lines 2c disposed in the second region 2b. The cutting lines 2c may be groove structures formed on either of two opposite surfaces of the sheet-like structure 2 or through grooves running through the two opposite surfaces of the sheet-like structure 2. The plurality of cutting lines 2c are disposed around the plurality of apertures 2a, and a plurality of independent single packages (as shown in FIG. 4) are obtained after cutting along the cutting lines 2c.

Moreover, the plurality of cutting lines 2c may be configured for stress relief during curing of a plastic packaging material of the plastic packaging layer 3.

In each single package, the ratio of the area of the chip 1 to the area of the plastic packaging layer 3 surrounding the chip 1 is 1:(1-15); the ratio of the area of the chip 1 to the area of the sheet-like structure 2 surrounding the chip 1 is 1:(1-15); and the area of the sheet-like structure 2 surrounding the chip 1 is less than or equal to the area of the plastic packaging layer 3.

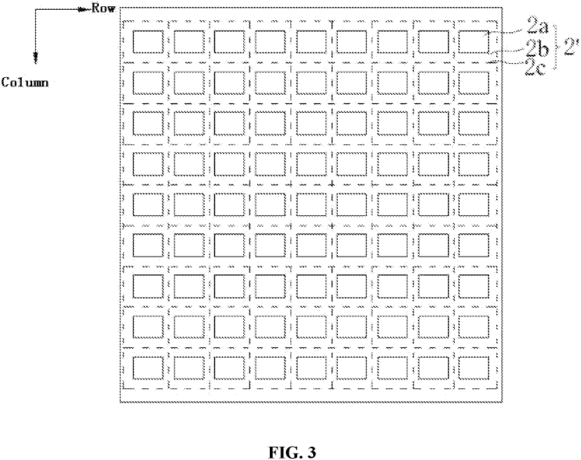

As shown in FIG. 3, another embodiment of the present invention further provides a sheet-like structure 2′, which differs from the sheet-like structure 2 illustrated in FIG. 2 only in that the outer edge of the sheet-like structure 2′ is, for example, rectangular. It should be noted that the shape of the outer edge of the sheet-like structure is not specifically limited in the present invention as long as it meets the condition that the chip 1 may be placed in each aperture 2a of the sheet-like structure 2, 2′ in the FOWLP process.

As shown in FIG. 1, in some embodiments of the present invention, the ratio of the thickness of the sheet-like structure 2, the film thickness of the plastic packaging layer 3 and the thickness of the chip 1 is (0.5-2):(1-2): 1. That is, if the thickness of the chip 1 is 1, the thickness of the sheet-like structure 2 is 0.5 to 2 times that of the chip 1, and the film thickness of the plastic packaging layer 3 is 1 to 2 times the thickness of the chip 1.

In some embodiments of the present invention, the sheet-like structure 2 is made of pure metal, alloy, organic resin or a combination thereof. The pure metal means that a material contains more than 95% of certain metal element, and the pure metal is preferably Cu.

In some embodiments, the alloy is for example hard alloy or stainless steel.

In some embodiments, the organic resin is thermosetting resin such as epoxy resin, phenolic resin, amino resin or unsaturated polyester resin.

In some embodiments, the sheet-like structure 2 may also be made from such inorganic materials as silicon and its oxides, nitride flakes and ceramic flakes. If the sheet-like structure 2 is made from an inorganic insulating material such as silicon oxide, silicon carbide and silicon nitride, it may be directly formed in the manufacturing process of the fan-out structure by thin film preparation processes such as physical vapor deposition and chemical vapor deposition, and provided with apertures by means of a patterning process (photoetching process).

It should be noted that the sheet-like structure 2, the plastic packaging layer 3 and the chip 1 may be of different thickness ratios and area ratios according to different materials selected.

| | | Young’s modulus/Gpa | Area ratio of sheet-like structure/plastic packaging layer/chip | Thickness ratio of sheet-like structure/plastic packaging layer/chip |
|---|---|---|---|---|
| Material of sheet-like structure | Copper sheet | 120 | (1-7):(1-8):1 | (1-2):(1-2):1 |
| | Stainless steel | 193 | (1-5):(1-10):1 | (0.5-1.5):(1-2):1 |
| | Alloy | 200 | (1-5):(1-10):1 | (0.5-1.5):(1-2):1 |
| | Epoxy resin | 22 | (1-15):(1-15):1 | (0.5-2):(1-2):1 |
| Plastic packaging material | | 7 | | |

Based on the different materials of the sheet-like structure 2, in case of the same thickness and area, different materials such as epoxy resin, copper sheet, stainless steel and alloy and their corresponding single packages are improved in three-point bending strength compared with single packages containing only the same plastic packaging material.

Specifically, the three-point bending strength of the single package added with the epoxy resin sheet-like structure is 1.2 to 1.5 times higher than that of the single package containing only the same plastic packaging material; the three-point bending strength of the single package added with the copper sheet-like structure is 2 to 2.8 times higher than that of the single package containing only the same plastic packaging material; the three-point bending strength of the single package added with the stainless steel sheet-like structure is 4 to 5 times higher than that of the single package containing only the same plastic packaging material; and the three-point bending strength of the single package added with the alloy sheet-like structure is 5 to 6 times higher than that of the single package containing only the same plastic packaging material. When being made from a material with a high Young’s modulus, the sheet-like structure 2 has significant beneficial effects on improving the package strength of the single package.

The process of manufacturing the wafer-level fan-out structure in FIG. 1 will be described in detail below with reference to FIG. 4, in which the wafer-level fan-out structure is for example manufactured using the FOWLP technology.

As shown in FIG. 4, a wafer-level carrier plate 10 is provided first, and a temporary bonding layer 20 is disposed on a surface of the carrier plate 10. The temporary bonding layer 20 is for example an adhesive layer.

A sheet-like structure 2 is attached to a surface of the temporary bonding layer 20, and a chip 1 is mounted in each aperture 2a. A back surface 1b of the chip 1 is temporarily bonded to the temporary bonding layer 20. A connection terminal 1a on an active surface of the chip 1 protrudes away from the temporary bonding layer 20. Preferably, the connection terminal 1a protrudes from the surface of the sheet-like structure 2 away from the carrier plate 10.

Since the Young’s modulus of the sheet-like structure 2 is higher than that of the plastic packaging material forming the plastic packaging layer 3, the sheet-like structure has certain rigidity and then can provide stable support to avoid warpage in manufacture of the reconstituted wafer. In addition, the plastic packaging layer 3 is made from a low-modulus plastic packaging material, for example, a thermoplastic material. The low-modulus plastic packaging material produces lower less shrinkage stress during curing and thus the reconstituted wafer tends to warp, making it easier to avoid warpage. The combination of the sheet-like structure 2 and the low-modulus plastic packaging material reduces the warpage without adversely affecting the package strength and the package stability of the wafer-level fan-out structure.

As shown in FIG. 4, an active surface side is coated with the plastic packaging material to form the plastic packaging layer 3 that covers both the chip 1 and the sheet-like structure 2. When being cured to form the plastic packaging layer 3, the plastic packaging material may shrink and release stress while changing from a liquid state or a semi-solid state to a solid state, and the stress may be released from apertures 2a and notches 2c to reduce the overall warpage of the reconstituted wafer The reconstituted wafer refers to an overall structure including the plurality of chips 1, the sheet-like structure 2 and the plastic packaging layer 3.

After the plastic packaging layer 3 covers the sheet-like structure 2 and the chip 1, the carrier plate 10 and the temporary bonding layer 20 are stripped from a back surface 1b side of the chip 1.

By means of the thinning process, the top surface of the plastic packaging layer 3 is thinned until the connection terminal 1a on the active surface of the chip 1 is exposed from the surface of the plastic packaging layer 3 away from the active surface.

A redistribution process is conducted to form a redistribution layer 4 on the surface of the thinned plastic packaging layer 3. The redistribution layer 4 includes conductive layers 4a and dielectric layers 4b, which are alternately arranged, and the multiple conductive layers 4a are electrically connected through dielectric through holes formed in the dielectric layers 4b. The dielectric through hole refers to a through hole running through the dielectric layer 4b in the packaging process, and the through hole is filled with a conductive material.

An interconnection structure 5 is formed on the surface of the redistribution layer 4 and electrically connected to the conductive layer 4a. The interconnection structure 5 may be a metal bump, a metal post, a solder ball, or a metal post with a tin cap.

Finally, a plurality of independent single packages are obtained by cutting through a dicing process.

As shown in FIGS. 1 and 4, the back surface 1b of the chip 1 is exposed because the plastic packaging layer 3 is formed on the active surface side. The exposed back surface 1b contributes to heat dissipation of the single packages.

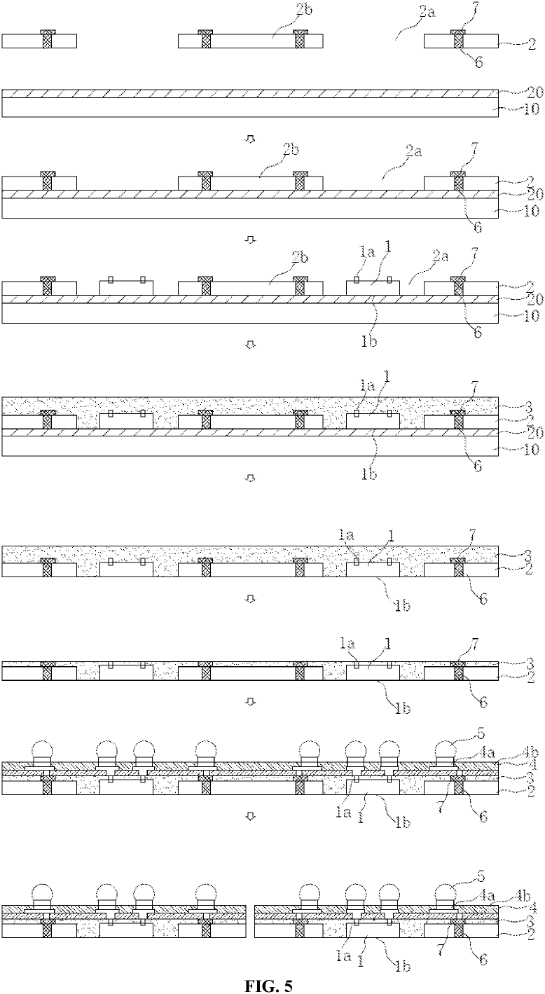

As shown in FIG. 5, the present invention further provides a schematic sectional view of a manufacturing process of another wafer-level fan-out structure. The another wafer-level fan-out structure manufactured in FIG. 5 differs from the wafer-level fan-out structure manufactured in FIG. 4 in that the another wafer-level fan-out structure shown in FIG. 5 further includes a conductor post 6 embedded into the sheet-like structure 2 and a pad bump 7 formed on a surface of the sheet-like structure 2, and the conductor post 6 and the pad bump 7 are electrically connected to each other.

Specifically, the active surface side is coated with the plastic packaging material to form the plastic packaging layer 3 plastic-packaging the sheet-like structure 2 and the chip 1, and the pad bump 7 is located in the plastic packaging layer 3.

Further, the plastic packaging layer 3 is thinned until the pad bump 7 and the connection terminal 1a on the active surface of the chip 1 are exposed together from the side of the plastic packaging layer 3 away from the active surface.

The conductive layer 4a in the redistribution layer 4 subsequently manufactured on the thinned plastic packaging layer 3 is electrically connected to the pad bump 7, which in turn allows the conductor post 6 in the sheet-like structure 2 to be electrically connected to the chip 1 and the conductive layer 4a in the redistribution layer 4 by the pad bump 7, providing more signal output terminals for signal output of the chip 1.

When the sheet-like structure 2 is made of a dielectric resin material, the conductor post 6 is for example a metal post made of a metal material, such as a cooper pillar, an aluminum pillar, a silver pillar and a palladium pillar, and may also be a post made from other conductive materials, which is not limited in the embodiment of the present invention.

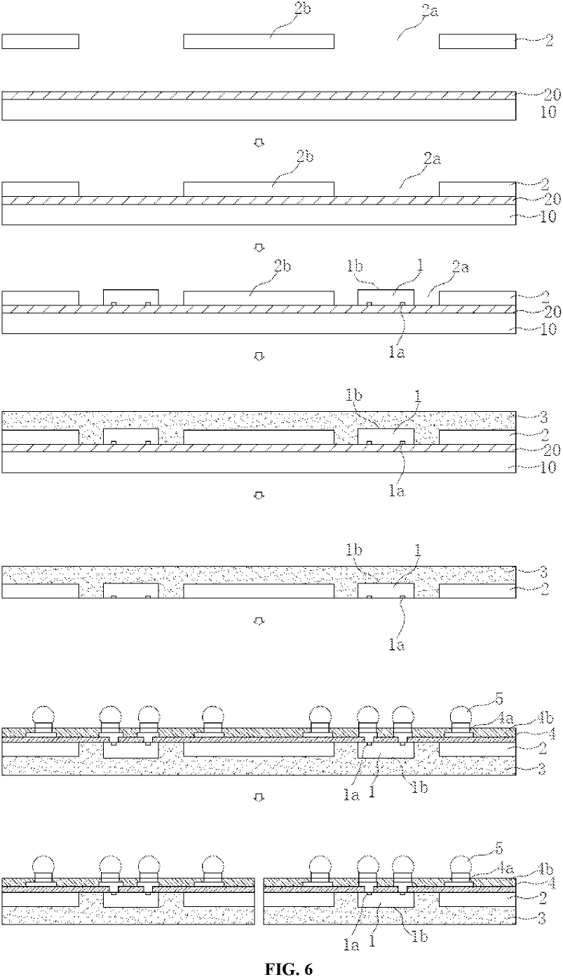

As shown in FIG. 6, the yet another wafer-level fan-out structure provided by the present invention differs from the wafer-level fan-out structure in FIG. 5 as follows. In the yet another wafer-level fan-out structure in FIG. 6,
1) the chip 1 is mounted in the aperture 2a of the sheet-like structure 2, and the connection terminal 1 a of the chip 1 is temporarily bonded to the temporary bonding layer 20;
2) the back surface 1b of the chip 1 is coated with the plastic packaging material to form the plastic packaging layer 3, and the plastic packaging layer 3 covers the chip 1 and the sheet-like structure 2 from the back surface 1b of the chip 1;
3) the temporary bonding layer 20 and the carrier plate 10 are stripped from the active surface side of the chip 1, and at this time, the connection terminals 1a on the active surface of the chip 1 and part of the surface of the sheet-like structure 2 are exposed from the side away from the plastic packaging layer 3, namely, the connection terminals 1a and the surface of the sheet-like structure 2 are directly exposed without being covered with the plastic packaging layer 3;
4) the redistribution layer 4 is manufactured on the active surface of the chip 1 and on the side surface of the sheet-like structure 2 away from the plastic packaging layer 3, and the conductive layer 4a in the redistribution layer 4 is electrically connected to the connection terminal 1a; and
5) the interconnection structure 5 is manufactured on a surface of the redistribution layer 4 and electrically connected to the conductive layer 4a in the redistribution layer 4.

In the wafer-level fan-out structure provided in FIG. 6, the active surface and the connection terminal 1a of the chip 1 are exposed since the side surface 1b of the chip 1 is coated with the plastic packaging material to manufacture the plastic packaging layer 3. Subsequently, the redistribution layer may be directly manufactured on the chip, omitting grinding and thinning steps in the process of manufacturing the wafer-level fan-out structures in FIG. 4 and FIG. 5. Therefore, the process steps are reduced, and the process efficiency is improved.

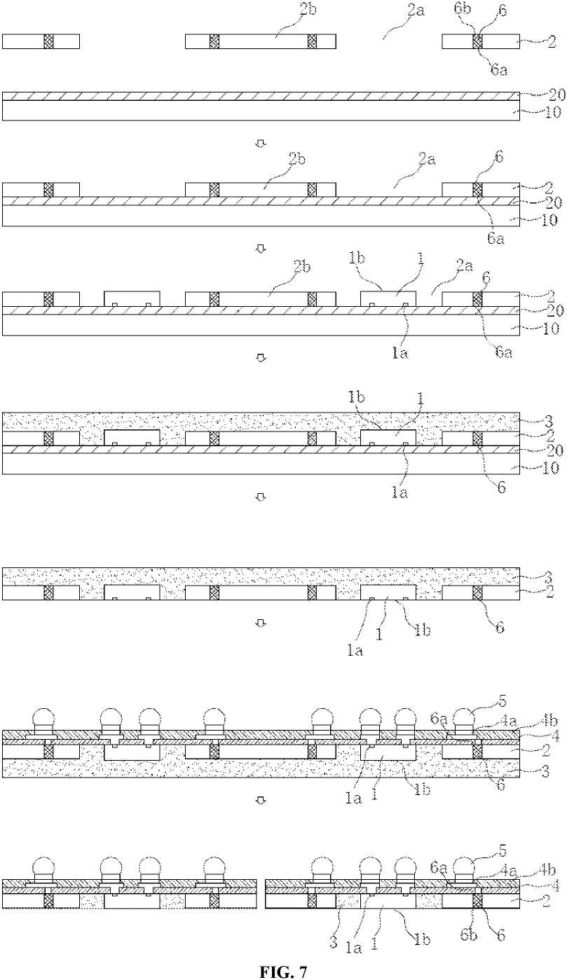

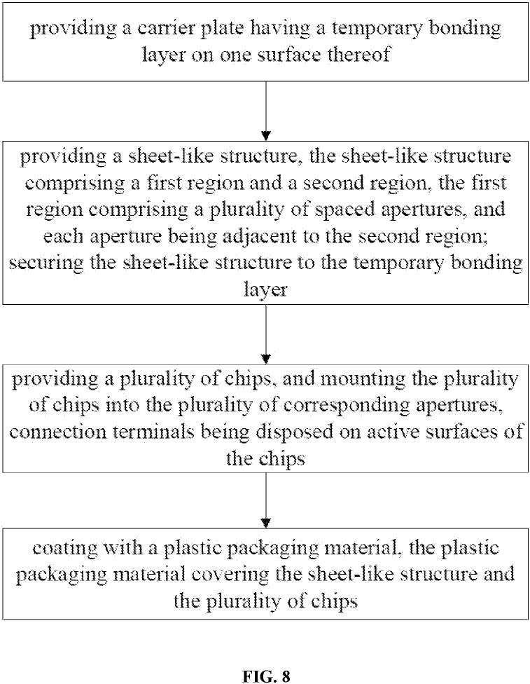

As shown in FIG. 7, the still another wafer-level fan-out structure provided by the present invention differs from the wafer-level fan-out structure shown in FIG. 6 in that the wafer-level fan-out structure in FIG. 7 further includes a conductor post 6 embedded into the sheet-like structure 2, and a connection end surface 6a of the conductor post 6 is exposed from the side of the sheet-like structure 2 not covered with the plastic packaging layer 3, i.e., the connection end surface 6a and the connection terminal 1a are located on the same side of a plastic packaging layer, and the connection end surface 6a is electrically connected to the conductive layer 4a in the redistribution layer 4.

Optionally, the conductor post 6 is for example a structure that runs through the sheet-like structure 2. After the plastic packaging layer 3 on the back surface 1b side of the chip 1 is thinned, another connection end surface 6b opposite to the connection end surface 6a may be exposed from the surface of the thinned plastic packaging layer 3 away from the back surface 1b.

In conjunction with the manufacturing processes of the wafer-level fan-out structures shown in FIGS. 4 to 7, the present invention further provides a manufacturing method of a wafer-level fan-out structure.

As shown in FIG. 8, the manufacturing method of the wafer-level fan-out structure according to the present invention includes:
providing a carrier plate having a temporary bonding layer disposed on one surface thereof;
providing a sheet-like structure including an aperture, and securing the sheet-like structure to the temporary bonding layer;
providing a chip, and mounting the chip into the aperture, a connection terminal being disposed on an active surface of the chip; and
providing a sheet-like structure, the sheet-like structure including a first region and a second region, the first region including a plurality of spaced apertures, and each aperture being adjacent to the second region; and securing the sheet-like structure to the temporary bonding layer;
providing a plurality of chips, and mounting the plurality of chips into the plurality of corresponding apertures, connection terminals being disposed on active surfaces of the chips; and
coating with a plastic packaging material, the plastic packaging material covering the sheet-like structure and the plurality of chips,
wherein the Young’s modulus of a plastic packaging layer is lower than that of the sheet-like structure, and the ratio of the area of the first region to the area of the second region is (0.5-2):1.

Optionally, the manufacturing method further includes: forming a redistribution layer on the active surface, the redistribution layer and the connection terminal being electrically connected to each other; and manufacturing an interconnection structure on a portion of the redistribution layer away from the active surface.

Optionally, the manufacturing method further includes: obtaining a plurality of independent single packages by cutting the wafer-level fan-out structure along cutting lines of the sheet-like structure.

Optionally, the manufacturing method further includes: making the connection terminal protrude in a direction away from the carrier plate, a back surface of the chip being temporarily bonded to the temporary bonding layer; coating the active surface side with a plastic packaging material, the plastic packaging material covering the sheet-like structure and the chip; stripping the temporary bonding layer and the carrier plate; thinning the plastic packaging layer until the connection terminal is exposed from the surface of the plastic packaging layer away from the active surface; and forming the redistribution layer on a surface of the thinned plastic packaging layer.

Optionally, the manufacturing method further includes: temporarily bonding the connection terminal to the temporary bonding layer, a back surface of the chip being away from the carrier plate; coating the back surface side with a plastic packaging material, the plastic packaging material covering the sheet-like structure and the chip to constitute a plastic packaging layer; stripping the temporary bonding layer and the carrier plate; and forming the redistribution layer on the surface of the sheet-like structure not covered with the plastic packaging layer and on the active surface.

The above manufacturing methods are all realized by the wafer-level process, and belong to the FOWLP technology. In the manufacturing methods, the sheet-like structure is a wafer-level sheet-like structure and includes the plurality of apertures; the carrier plate and the wafer-level sheet-like structure are adapted to each other; the plurality of chips are provided, and each chip is mounted into the corresponding aperture; and the plastic packaging material is coated and cured for plastic-packaging the chips and the sheet-like structure to form the reconstituted wafer including a plurality of single packages.

In summary, the present invention provides the wafer-level fan-out structure and the manufacturing method thereof, in which the Young’s modulus of the plastic packaging layer is controlled to be low so as to be able to reduce warpage caused by the plastic packaging layer during reconstitution of the wafer; and the sheet-like structure with a high Young’s modulus is embedded into the plastic packaging layer, so that the package strength can be improved on the one hand, and on the other hand, by use of rigidity of the sheet-like structure, the warpage caused by the plastic packaging layer during reconstitution of the wafer can also be reduced, further reducing the warpage of each single package in the fan-out structure. Furthermore, selecting the area ratio of the apertures in the sheet-like structure to the sheet-like structure on the one hand effectively reduces the warpage of the wafer-level fan-out structure, and on the other hand, provides enough support to improve the package strength of the wafer-level fan-out structure.

The present invention has been described by the above-mentioned related embodiments which, however, are only examples for implementing the present invention. In addition, the technical features involved in the different embodiments of the present invention described above can be combined with each other as long as they do not conflict with each other. It is necessary to point out that the present invention may have many other embodiments, and those skilled in the art can make various corresponding changes and modifications according to the present invention without departing from the spirit and essence of the present invention, and these corresponding changes and modifications should all fall within the scope of protection of the appended claims of the present invention.

What is claimed is:

1. A wafer-level fan-out structure, comprising:
a plurality of chips, a sheet-like structure and a plastic packaging layer, wherein the plastic packaging layer covers the plurality of chips and the sheet-like structure; the sheet-like structure comprising a first region and a second region, the first region comprising a plurality of spaced apertures, and each aperture being adjacent to the second region; the plurality of chips and the plurality of apertures are in one-to-one correspondence, and each chip is located in the corresponding aperture; and
a Young’s modulus of the plastic packaging layer is lower than that of the sheet-like structure, and a ratio of an area of the first region to an area of the second region is (0.5-2):1.

2. The wafer-level fan-out structure according to claim 1, wherein each chip comprises an active surface and a connection terminal, the connection terminal being located on the active surface; and the wafer-level fan-out structure further comprises:
a redistribution layer disposed on an active surface side and electrically connected to the connection terminal; and
an interconnection structure which is disposed on a side surface of the redistribution layer away from the connection terminal, and is electrically connected to the redistribution layer.

3. The wafer-level fan-out structure according to claim 2, wherein the plastic packaging layer covers the chip and the sheet-like structure on the active surface side, the connection terminal is exposed from a surface of the plastic packaging layer away from the active surface, and the redistribution layer is disposed on a surface of the plastic packaging layer.

4. The wafer-level fan-out structure according to claim 2, wherein the chip comprises a back surface facing away from the active surface; the plastic packaging layer covers the chip and the sheet-like structure on a back surface side; the active surface is not covered with the plastic packaging layer; and the redistribution layer is disposed on the active surface and a surface of the sheet-like structure not covered with the plastic packaging layer.

5. The wafer-level fan-out structure according to claim 2, wherein the sheet-like structure further comprises a metal post, the metal post is embedded into the second region and comprises a connection end surface, the connection end surface and the connection terminal are located on the same side, and the connection end surface and the redistribution layer are electrically connected to each other.

6. The wafer-level fan-out structure according to claim 1, wherein a ratio of a thickness of the sheet-like structure, a film thickness of the plastic packaging layer and a thickness of the chip is (0.5-2):(1-2):1.

7. The wafer-level fan-out structure according to claim 1, wherein the sheet-like structure is made of pure metal, alloy, organic resin or a combination thereof.

8. The wafer-level fan-out structure according to claim 7, wherein the alloy is hard alloy or stainless steel.

9. The wafer-level fan-out structure according to claim 7, wherein the organic resin is epoxy resin, phenolic resin, amino resin or unsaturated polyester resin.

10. The wafer-level fan-out structure according to claim 1, wherein the sheet-like structure further comprises a plurality of cutting lines, the plurality of cutting lines are located in the second region and surround the plurality of apertures, and a plurality of single packages are obtained by cutting the wafer-level fan-out structure along the plurality of cutting lines.

11. The wafer-level fan-out structure according to claim 10, wherein in each single package, a ratio of an area of the chip to an area of the plastic packaging layer surrounding the chip is 1:(1-15); and a ratio of the area of the chip to an area of the sheet-like structure surrounding the chip is 1:(1-15), wherein the area of the sheet-like structure surrounding the chip is less than or equal to the area of the plastic packaging layer.

12. A manufacturing method of a wafer-level fan-out structure, comprising:
providing a carrier plate having a temporary bonding layer on one surface thereof;
providing a sheet-like structure, the sheet-like structure comprising a first region and a second region, the first region comprising a plurality of spaced apertures, and each aperture being adjacent to the second region; securing the sheet-like structure to the temporary bonding layer;
providing a plurality of chips, and mounting the plurality of chips into the plurality of corresponding apertures, connection terminals being disposed on active surfaces of the chips; and
coating with a plastic packaging material, the plastic packaging material covering the sheet-like structure and the plurality of chips;
wherein a Young’s modulus of the plastic packaging layer is lower than that of the sheet-like structure, and a ratio of an area of the first region to an area of the second region is (0.5-2):1.

13. The manufacturing method of the wafer-level fan-out structure according to claim 12, further comprising:
forming a redistribution layer on the active surface, the redistribution layer and the connection terminal being electrically connected to each other; and
manufacturing an interconnection structure on a portion of the redistribution layer away from the active surface.

14. The manufacturing method of the wafer-level fan-out structure according to claim 13, further comprising:
making the connection terminal protrude away from the carrier plate, a back surface of the chip being temporarily bonded to the temporary bonding layer;
coating an active surface side with a plastic packaging material, the plastic packaging material covering the sheet-like structure and the chip;
stripping the temporary bonding layer and the carrier plate;
thinning the plastic packaging layer until the connection terminal is exposed from a surface of the plastic packaging layer away from the active surface; and
forming the redistribution layer on a surface of the thinned plastic packaging layer.

15. The manufacturing method of the wafer-level fan-out structure according to claim 13, further comprising:
temporarily bonding the connection terminal to the temporary bonding layer, a back surface of the chip being away from the carrier plate;
coating a back surface side with a plastic packaging material, the plastic packaging material covering the sheet-like structure and the chip to constitute the plastic packaging layer;
stripping the temporary bonding layer and the carrier plate; and
forming the redistribution layer on a surface of the sheet-like structure not covered with the plastic packaging layer and on the active surface.
